(19) United States
(12) Patent Application Publication
(10) Pub. No.: US 2026/0118781 A1
(43) Pub. Date: Apr. 30, 2026

(54) MODULAR, PARTIALLY-REDUNDANT CONVERTER SYSTEM WITH DC/DC CONVERTERS CONNECTED IN SERIES ON THE OUTPUT SIDE

(71) Applicant: Carl Zeiss SMT GmbH, Oberkochen (DE)

(72) Inventor: Oliver HERBST, Aalen (DE)

(21) Appl. No.: 19/429,816

(22) Filed: Dec. 22, 2025

Related U.S. Application Data
(63) Continuation of application No. PCT/EP2024/068120, filed on Jun. 27, 2024.

(30) Foreign Application Priority Data
Jun. 28, 2023 (DE) 10 2023 206 070.1

(51) Int. Cl. G03F 7/00; G02B 26/08; H02P 23/00; H03F 3/04; H03K 17/687

(52) U.S. Cl. CPC G03F 7/70991; G02B 26/0816; G03F 7/70141; G03F 7/70258; G03F 7/70525; G03F 7/70825; H02P 23/00; H03F 3/04; H03K 17/6872

(57) ABSTRACT

A control device controls an actuator of an optical system. An optical system comprises such a control device. A lithography apparatus comprises such an optical system.

### CROSS-REFERENCE TO RELATED APPLICATIONS

The present application is a continuation of, and claims benefit under 35 USC 120 to, international application No. PCT/EP2024/068120, filed Jun. 27, 2024, which claims benefit under 35 USC 119 of German Application No. 10 2023 206 070.1, filed Jun. 28, 2023. The entire disclosure of each of these applications is incorporated by reference herein.

### FIELD

The present disclosure relates to a control device for controlling an actuator of an optical system, to an optical system comprising such a control device, and to a lithography apparatus comprising such an optical system.

### BACKGROUND

Microlithography apparatuses having actuatable optical elements, such as for example microlens arrays or micromirror arrays, are known. Microlithography is used to produce microstructured components, such as for example integrated circuits. The microlithography process is carried out using a lithography apparatus having an illumination system and a projection system.

Driven by the desire for ever smaller structures in the production of integrated circuits, EUV lithography apparatuses that use light at a wavelength in the range of 0.1 nm to 30 nm, for example 13.5 nm, are currently under development. Since, in general, most materials absorb light at this wavelength, such EUV lithography apparatuses commonly use reflective optics units, i.e. mirrors, instead of refractive optics units, i.e. lenses, as used previously.

The image of a mask (reticle) illuminated by way of the illumination system is projected here by way of the projection system onto a substrate, for example a silicon wafer, which is coated with a light-sensitive layer (photoresist) and is arranged in the image plane of the projection system, in order to transfer the mask structure to the light-sensitive coating of the substrate. Actuatable optical elements can be used to improve the imaging of the mask on the substrate. For example, wavefront aberrations during exposure, which result in magnified and/or blurred image representations, can be compensated for.

For example, a MEMS actuator (MEMS; microelectromechanical system) or a PMN actuator (PMN; lead magnesium niobate) may be used as actuator. A PMN actuator can help allow path positioning in the sub-micrometer range or sub-nanometer range. Due to the application of a DC voltage, the actuator, whose actuator elements are stacked on top of one another, can be subject to a force which causes a specific longitudinal extension. The position set by way of the DC voltage (DC; direct current) may be adversely affected by external electromechanical crosstalk at the resonance points of the actuator controlled by the DC voltage that generally arise. MEMS mirrors and actuators suitable for controlling them are described for example in DE 10 2016 213 025 A1.

Lithography apparatuses are relatively complex systems comprising a relatively large number of actuators to be controlled. Control of the actuators can place very high demands on fail-safety of the voltage supply. The probability of a failure in such a system can be relatively high. Therefore, it can be desirable to try to ensure that a failure of a subcomponent does not mean total failure of the system. In addition, the installation space for the control devices for controlling the actuators within the lithography apparatus is relatively limited.

In order to increase fail-safety, a redundant interconnection of a plurality of power supply units is conventionally used. However, a redundant interconnection of power supply units usually involves keeping more power supply unit power available. In this case, the power supply unit power can be correlated with the installation space. Generally, more power supply unit power therefore uses more installation space.

As a consequence, normally redundant interconnection of power supply units can involve keeping double the power supply unit power available, which in turn can lead to a doubling of the installation space. Furthermore, power supply units that provide unusual voltage levels usually have a relatively low power density and/or involve relatively complex custom development. A a failure, for example a short circuit, of a power supply unit in the voltage supply path for the actuator can cause a collapse of the voltage supply for the actuator.

### SUMMARY

The present disclosure seeks to improve control of an actuator of an optical system.

According to a first aspect, the disclosure provides a control device for controlling an actuator for actuating an optical element of an optical system. The control device comprises:
an amplifier configured to receive a supply voltage provided at an input node and provide a control voltage for the actuator at an output node, and
a supply device which serves to provide the supply voltage, is coupled to the input node and comprises a series connection which can be coupled between the input node and ground and comprises a plurality N, with N≥2, of DC/DC converters which serve to provide a respective DC voltage and a number M, with M≥1, of further DC/DC converters which can be connected in series with the series connection and serve to provide a DC voltage.

The respective DC/DC converter can be in the form of a respective power supply unit. All DC/DC converters of the N DC/DC converters and the M further DC/DC converters (reserve DC/DC converters) can be independent of one another, for example galvanically isolated from one another. The respective DC/DC converter may optionally also have a separate input node with respective ground potential. The ground potential at the input of the DC/DC converters can be independent of the ground potential at the output of the DC/DC converters since these ground potentials can be galvanically isolated from each other.

With the present supply device for the amplifier of the control device, the DC/DC converters or further DC/DC converters can be intelligently redundantly interconnected, so that an optimum of reliability and installation space can be ensured. In addition, the interconnection formed by the present series connection with the N DC/DC converters and the M further DC/DC converters that can be connected in series with this series connection ensures that the failure of a single DC/DC converter in the path of the voltage supply allows continued operation without restriction. This can result in increased fail-safety compared with a normal voltage supply.

The N DC/DC converters in the series connection can be designed such that a sum of their DC voltages provided in the connected state corresponds to a predetermined target value for the supply voltage. Accordingly, the plurality N and the DC voltages can be chosen such that efficient “commercial off the shelf” components can be used as DC/DC converters and as further DC/DC converters. For example, if the target value for the supply voltage is 144 V, then N=3 can be chosen, and the output voltage of the respective DC/DC converter can be chosen to be 48 V. Hence each of the three DC/DC converters in the series connection can provide 48 V on the output side in the connected state, yielding the sum of 144 V (144 V=48 V+48 V+48 V).

In the case of a fault with one of the DC/DC converters from the N DC/DC converters in the series connection, the faulty DC/DC converter can be switched off or bridged, and one of the M reserve DC/DC converters can be connected. In fault-free operation, the M reserve DC/DC converters are not connected and do not contribute to the voltage at the input node of the amplifier.

For example, the actuator is a MEMS actuator, a capacitive actuator, for example a PMN actuator (PMN; lead magnesium niobate), or a PZT actuator (PZT; lead zirconate titanate), or a LiNbO3 (lithium niobate) actuator. For example, the actuator is configured to actuate an optical element in the optical system. Examples of such an optical element comprise lens elements, mirrors and adaptive mirrors.

The optical system can be a projection optics unit of the lithography apparatus or projection exposure apparatus. However, the optical system may also be an illumination system. The projection exposure apparatus may be an EUV lithography apparatus. EUV stands for “extreme ultraviolet” and denotes a wavelength of the operating light between 0.1 nm and 30 nm. The projection exposure apparatus may also be a DUV lithography apparatus. DUV stands for “deep ultraviolet” and denotes a wavelength of the operating light between 30 nm and 250 nm.

According to an embodiment, a respective controllable switch is assigned to each of the N DC/DC converters and each of the M further DC/DC converters. The respective switch is configured to connect or short the respective assigned DC/DC converter in order to provide the supply voltage.

Hence the switches can be used to set which of the N DC/DC converters or which of the M further DC/DC converters can contribute to the provision of the supply voltage at the input node of the amplifier and which do not. In fault-free operation, the switches can be switched in such a way that the N DC/DC converters provide their DC voltage on the output side, and hence the sum thereof can form the supply voltage at the input node of the amplifier. In the event of a fault, the controllable switches can be controlled such that the faulty DC/DC converter from the N DC/DC converters can be bridged and one of the M further DC/DC converters is connected in return such at the output-side DC voltage of the latter may contribute to the supply voltage at the input node of the amplifier.

According to an embodiment, the N DC/DC converters are designed such that the sum of their DC voltages provided in the connected state corresponds to a predetermined target value for the supply voltage.

For example, if the target value for the supply voltage is 144 V and DC/DC converters which provide 48 V on the output side are used, then N=3 is chosen (144 V=48 V+48 V+48 V).

In the present case, “connected” means that the relevant DC/DC converter (or the relevant further DC/DC converter) is part of the series connection between the input node of the amplifier and ground such that the DC voltage provided by the relevant DC/DC converter (or the further DC/DC converter) contributes to the supply voltage present at the input node.

According to an embodiment, provision is made for a control unit, which is configured to control the N DC/DC converters and the M further DC/DC converters. The control unit is implemented for example in software, as a discrete circuit or as an ASIC, and controls the DC/DC converters.

According to an embodiment, in the event of a detected fault in a specific DC/DC converter from the connected N DC/DC converters, the control unit is configured to both control the switch assigned to the specific DC/DC converter in such a way that the specific DC/DC converter is shorted and control a switch assigned to a specific one of the further DC/DC converters in such a way that the specific further DC/DC converter is connected.

A simple example with N=2 and M=1 can illustrate this. In the fault-free case, the two DC/DC converters in the series connection provide the supply voltage at the input node of the amplifier. If a fault is now detected in one of the two DC/DC converters, then the switch assigned to the faulty DC/DC converter is closed and the switch assigned to the reserve DC/DC converter is opened such that the reserve DC/DC converter is able to provide its DC voltage on the output side for the supply voltage at the first node.

According to an embodiment, the control device comprises an evaluation device for detecting faults in the N DC/DC converters. In this case, the evaluation device is configured for example to detect a fault with a respective one of the N DC/DC converters.

According to an embodiment, the evaluation device comprises a respective evaluation circuit for each of the N DC/DC converters. In this case, the switch assigned to the respective DC/DC converter is coupled between the output terminals of the DC/DC converter. The respective evaluation circuit is connected in parallel with the assigned switch.

The respective evaluation circuit can be configured to detect whether or not the DC/DC converter assigned to the evaluation circuit outputs the correct DC voltage on the output side.

According to a further embodiment, the respective evaluation circuit comprises:
a first voltage divider connected to a first one of the output terminals,
a voltage divider connected to a second one of the output terminals and
a comparator for providing a comparison result, the non-inverting input of which is coupled to the center tap of the first voltage divider and the inverting input of which is coupled to the center tap of the second voltage divider.

The comparison result provided by the evaluation circuit indicates whether or not the assigned DC/DC converter provides the correct DC voltage on the output side for the input node of the amplifier. No fault is detected should the comparison result yield that the DC voltage provided by the DC/DC converter corresponds to a predefined target value. A fault is detected otherwise.

According to an embodiment, the control unit is configured to receive the N comparison results provided by the comparators of the N evaluation circuits and, on the basis thereof, provide a plurality N of control signals for controlling the N switches assigned to the N DC/DC converters, a number M of control signals for controlling the M switches assigned to the M further DC/DC converters and an enable signal for connecting the specific further DC/DC converter in the event of the detected fault in the specific DC/DC converter.

The control unit uses the control signals to set which of the N DC/DC converters and the M DC/DC converters form the series connection of connected DC/DC converters between the input node of the amplifier and ground. In the fault-free state, the N DC/DC converters form the series connection between the input node of the amplifier and ground. If one of the N DC/DC converters fails or is faulty, this faulty DC/DC converter is bridged and one of the M further DC/DC converters takes its place as part of the series connection between the input node of the amplifier and ground, and so the DC voltage provided on the output side of the further DC/DC converter contributes to the supply voltage.

According to an embodiment, the amplifier is configured to amplify the supply voltage provided at the input node into the control voltage, provided at the output node, for the actuator using a quiescent current of the amplifier. In this case, a provision unit is provided, which is configured to set the quiescent current for the amplifier on the basis of a desired specific dynamic for the amplifier. The provision unit can be configured to set the quiescent current for the amplifier on the basis of the determined desired dynamic for the amplifier and feed the quiescent current into the output node of the amplifier.

For example, the quiescent current is the current that flows through the amplifier even if the latter is not dynamically active. The quiescent current is used to set the operating point at the output node. In the present case, this operating point is briefly shifted by the provision unit depending on the desired dynamic. The quiescent current may also be referred to as the bias current.

In the present embodiment, the quiescent current of the amplifier is set depending on the desired dynamic for the amplifier. The desired dynamic specifies the desired dynamics of the amplifier at a specific point in time. For example, if the capacitive actuator to be controlled should be recharged quickly, the desired dynamic is large, and the quiescent current is quickly increased.

The following example may illustrate this. For example, the desired dynamic is based on a change in the input voltage of the amplifier, optionally on a derivative of the input voltage du/dt. In this example, a high du/dt corresponds to a high desired dynamic. As a result, the quiescent current is increased for example proportionally in the case of a high du/dt. In other words, du/dt is directly proportional to the change in the quiescent current. For a negative du/dt, the change and hence the effect in the other direction becomes effective. Here, the quiescent current is reduced, which can reduce the power consumption. In other words, a high quiescent current is set only in the case of a high desired dynamic in order to be able to accordingly provide a short response time of the actuator. At all other times, only a small quiescent current is used so as to minimize the corresponding waste heat. As a result, the temporarily increased quiescent current temporarily provides a high recharge speed. Otherwise, a low quiescent current is used, especially at a constant actuator position, to reduce the waste heat. The present control device causes less power loss, hence less waste heat and hence the possibility of simplifying the cooling concept of the optical system.

According to an embodiment, the amplifier is in the form of a switching amplifier, wherein a filter unit having at least one inductor can be connected between the actuator and the switching amplifier. The filter unit receives the control voltage provided by the amplifier and provides a filtered control voltage on the output side.

For example, the filter unit forms a low-pass filter which smooths the control voltage over time. The filtered control voltage can correspond to a mean value of the control voltage over time. For example, the filter unit may take the form of a multi-stage filter and comprise both inductors and capacitors. The filter unit can be configured to filter the amplified signal, i.e. the control voltage, such that a remaining AC component in the filtered control voltage is less than 0.1% of the amplitude. The filter unit may also be referred to as a demodulator.

The filter unit can be designed at least as a second-order filter. The filter unit can be designed as a higher-order, for example fourth-order, filter. Higher filter orders may be realized for example by a cascade of lower-order filters. In this case, the filter unit is designed as a passive filter for example. The filter unit for example has a cut-off frequency from a range of 1 kHz-10 kHz. A slope of the filter unit and also a type of the filter unit, for example whether the filter unit is embodied as a Butterworth filter, a Chebyshev filter, a Bessel filter, a Sallen-key filter or some other type of filter, are selected specifically for a respective application.

According to a further embodiment, the amplifier is a class A amplifier. The class A amplifier exhibits only little signal distortion and therefore provides precise actuator control.

According to an embodiment, the amplifier is a class AB amplifier. The class AB amplifier is a suitable alternative to the proposed class A amplifier.

According to a second aspect, the disclosure provides an optical system comprising a number of actuatable optical elements, wherein each of the actuatable optical elements of the number is assigned an actuator, wherein each actuator is assigned a control device for controlling the actuator according to the first aspect or according to one of the embodiments of the first aspect.

The optical system comprises for example a micromirror array and/or a microlens element array comprising a multiplicity of optical elements able to be actuated independently of one another.

In some embodiments, groups of actuators may be defined, wherein all actuators of a group are assigned the same control device.

According to an embodiment, the optical system is embodied as an illumination optics unit or as a projection optics unit of a lithography apparatus.

According to an embodiment, the optical system comprises a vacuum housing in which the actuatable optical elements, the assigned actuators and the control device are arranged.

According to a third aspect, the disclosure provides a lithography apparatus that comprises an optical system according to the second aspect or according to one of the embodiments of the second aspect.

The lithography apparatus is for example an EUV lithography apparatus, the operating light of which is in a wavelength range of 0.1 nm to 30 nm, or a DUV lithography apparatus, the operating light of which is in a wavelength range of 30 nm to 250 nm.

“A(n)” in the present case should not necessarily be understood as restrictive to exactly one element. Rather, a plurality of elements, such as two, three or more, may also be provided. Any other numeral used here should also not be understood as a restriction to exactly the stated number of elements. Rather, unless indicated otherwise, numerical variances upward and downward are possible.

Further possible implementations of the disclosure also comprise combinations not explicitly mentioned of features or embodiments described hereinabove or hereinafter with regard to the exemplary embodiments. A person skilled in the art will also add individual aspects as improvements or supplementations to the respective basic form of the disclosure.

Further configurations and aspects of the disclosure are the subject of the dependent claims and of the exemplary embodiments of the disclosure that are described hereinafter. The disclosure will be explained in more detail hereinafter on the basis of certain embodiments with reference to the appended figures.

### BRIEF DESCRIPTION OF THE DRAWINGS

FIG. 1 shows a schematic meridional section of a projection exposure apparatus for EUV projection lithography;

FIG. 2 shows a schematic illustration of an embodiment of an optical system;

FIG. 3 shows a schematic block diagram of a first embodiment of a control device for controlling an actuator for actuating an optical element in an optical system;

FIG. 4 shows the control device according to FIG. 3 in the event of a fault and its subsequent response;

FIG. 5 shows a schematic block diagram of a second embodiment of a control device for controlling an actuator for actuating an optical element in an optical system;

FIG. 6 shows the control device according to FIG. 5 in the event of a fault and its subsequent response; and

FIG. 7 shows a schematic block diagram of an embodiment of a supply device for providing the supply voltage for the control device and an embodiment of an evaluation device for detecting faults in the DC/DC converters of the supply device.

### DETAILED DESCRIPTION

In the figures, identical or functionally identical elements have been provided with the same reference signs, unless indicated otherwise. It should also be noted that the illustrations in the figures are not necessarily true to scale.

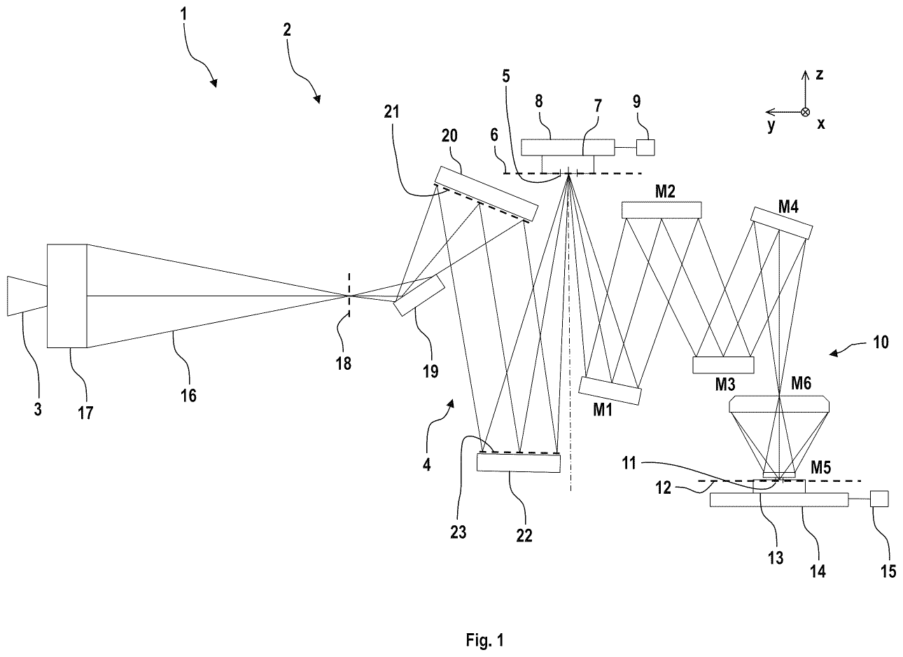

FIG. 1 shows an embodiment of a projection exposure apparatus 1 (lithography apparatus), for example an EUV lithography apparatus. An embodiment of an illumination system 2 of the projection exposure apparatus 1 has, in addition to a light or radiation source 3, an illumination optics unit 4 for illuminating an object field 5 in an object plane 6. In an alternative embodiment, the light source 3 may also be provided as a module separate from the rest of the illumination system 2. In this case, the illumination system 2 does not comprise the light source 3.

A reticle 7 arranged in the object field 5 is exposed. The reticle 7 is held by a reticle holder 8. The reticle holder 8 is displaceable by way of a reticle displacement drive 9, for example in a scanning direction.

FIG. 1 depicts, for explanation purposes, a Cartesian coordinate system with an x-direction x, a y-direction y and a z-direction z. The x-direction x runs perpendicularly into the plane of the drawing. The y-direction y runs horizontally, and the z-direction z runs vertically. The scanning direction runs along the y-direction y in FIG. 1. The z-direction z runs perpendicularly to the object plane 6.

The projection exposure apparatus 1 comprises a projection optics unit 10. The projection optics unit 10 is used to image the object field 5 into an image field 11 in an image plane 12. The image plane 12 extends parallel to the object plane 6. Alternatively, an angle between the object plane 6 and the image plane 12 that differs from 0° is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, for example along the y-direction y. The displacement, firstly, of the reticle 7 by way of the reticle displacement drive 9 and, secondly, of the wafer 13 by way of the wafer displacement drive 15 can be implemented so as to be synchronized with one another.

The light source 3 is an EUV radiation source. The light source 3 emits for example EUV radiation 16, which is also referred to below as used radiation, illumination radiation or illumination light. For example, the used radiation 16 has a wavelength in the range between 5 nm and 30 nm. The light source 3 may be a plasma source, for example an LPP (laser produced plasma) source or a GDPP (gas discharge produced plasma) source. It may also be a synchrotron-based radiation source. The light source 3 may be a free electron laser (FEL).

The illumination radiation 16 emanating from the light source 3 is focused by a collector 17. The collector 17 may be a collector having one or more ellipsoidal and/or hyperboloidal reflection surfaces. The illumination radiation 16 may be incident on the at least one reflection surface of the collector 17 with grazing incidence (GI), i.e. at angles of incidence of greater than 45°, or with normal incidence (NI), i.e. at angles of incidence of less than 45°. The collector 17 may be structured and/or coated, firstly to optimize its reflectivity for the used radiation and secondly to suppress extraneous light.

Downstream of the collector 17, the illumination radiation 16 propagates through an intermediate focus in an intermediate focal plane 18. The intermediate focal plane 18 may represent a separation between a radiation source module, having the light source 3 and the collector 17, and the illumination optics unit 4.

The illumination optics unit 4 comprises a deflection mirror 19 and, arranged downstream thereof in the beam path, a first facet mirror 20. The deflection mirror 19 may be a plane deflection mirror or alternatively a mirror with a beam-influencing effect going beyond the pure deflection effect. In an alternative to that or in addition, the deflection mirror 19 may take the form of a spectral filter that separates a used light wavelength of the illumination radiation 16 from extraneous light of a wavelength differing therefrom. If the first facet mirror 20 is arranged in a plane of the illumination optics unit 4 which is optically conjugate to the object plane 6 as a field plane, it is also referred to as a field facet mirror. The first facet mirror 20 comprises a multiplicity of individual first facets 21, which can also be referred to as field facets. Only some of these first facets 21 are illustrated in FIG. 1 by way of example.

The first facets 21 may be embodied as macroscopic facets, for example as rectangular facets or as facets with an arcuate or partly circular edge contour. The first facets 21 may be embodied as plane facets or alternatively as convexly or concavely curved facets.

As is known from DE 10 2008 009 600 A1, for example, the first facets 21 themselves may each also be composed of a multiplicity of individual mirrors, for example a multiplicity of micromirrors. The first facet mirror 20 may for example take the form of a microelectromechanical system (MEMS system). For details, reference is made to DE 10 2008 009 600 A1.

The illumination radiation 16 travels horizontally, i.e. in the y-direction y, between the collector 17 and the deflection mirror 19.

In the beam path of the illumination optics unit 4, a second facet mirror 22 is disposed downstream of the first facet mirror 20. If the second facet mirror 22 is arranged in a pupil plane of the illumination optics unit 4, it is also referred to as a pupil facet mirror. The second facet mirror 22 may also be spaced apart from a pupil plane of the illumination optics unit 4. In this case, the combination of the first facet mirror 20 and the second facet mirror 22 is also referred to as a specular reflector. Specular reflectors are known from US 2006/0132747 A1, EP 1 614 008 B1 and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which may for example have a round, rectangular or else hexagonal boundary, or may alternatively be facets composed of micromirrors. In this regard, reference is likewise made to DE 10 2008 009 600 A1.

The second facets 23 may have planar or, alternatively, convexly or concavely curved reflection surfaces.

The illumination optics unit 4 thus forms a doubly faceted system. This is also referred to as a fly's eye integrator.

It may be desirable to arrange the second facet mirror 22 not exactly in a plane that is optically conjugate to a pupil plane of the projection optics unit 10. For example, the second facet mirror 22 may be arranged so as to be tilted in relation to a pupil plane of the projection optics unit 10, as described for example in DE 10 2017 220 586 A1.

The second facet mirror 22 is used to image the individual first facets 21 into the object field 5. The second facet mirror 22 is the last beam-shaping mirror or else actually the last mirror for the illumination radiation 16 in the beam path upstream of the object field 5.

In a further embodiment (not depicted here) of the illumination optics unit 4, a transfer optics unit contributing for example to the imaging of the first facets 21 into the object field 5 may be arranged in the beam path between the second facet mirror 22 and the object field 5. The transfer optics unit may comprise exactly one mirror, or alternatively two or more mirrors arranged one behind another in the beam path of the illumination optics unit 4. The transfer optics unit may for example comprise one or two normal-incidence mirrors (NI mirrors) and/or one or two grazing-incidence mirrors (GI mirrors).

In the embodiment shown in FIG. 1, the illumination optics unit 4 has exactly three mirrors downstream of the collector 17, specifically the deflection mirror 19, the first facet mirror 20 and the second facet mirror 22.

In a further embodiment of the illumination optics unit 4, the deflection mirror 19 may also be omitted, and so the illumination optics unit 4 may then have exactly two mirrors downstream of the collector 17, specifically the first facet mirror 20 and the second facet mirror 22.

The imaging of the first facets 21 into the object plane 6 via the second facets 23 or using the second facets 23 and a transfer optics unit is regularly only approximate imaging.

The projection optics unit 10 comprises a plurality of mirrors Mi, which are consecutively numbered in accordance with their arrangement in the beam path of the projection exposure apparatus 1.

In the example illustrated in FIG. 1, the projection optics unit 10 comprises six mirrors M1 to M6. Alternatives with four, eight, ten, twelve or any other number of mirrors Mi are likewise possible. The projection optics unit 10 is a doubly obscured optics unit. The penultimate mirror M5 and the last mirror M6 each have a passage opening for the illumination radiation 16. The projection optics unit 10 has an image-side numerical aperture that is greater than 0.5 and may also be greater than 0.6 and for example may be 0.7 or 0.75.

Reflection surfaces of the mirrors Mi may take the form of free-form surfaces without an axis of rotational symmetry. Alternatively, the reflection surfaces of the mirrors Mi may be designed as aspherical surfaces with exactly one axis of rotational symmetry of the reflection surface shape. Just like the mirrors of the illumination optics unit 4, the mirrors Mi may have highly reflective coatings for the illumination radiation 16. These coatings can be designed as multilayer coatings, for example with alternating layers of molybdenum and silicon.

The projection optics unit 10 has a large object-image shift in the y-direction y between a y-coordinate of a center of the object field 5 and a y-coordinate of the center of the image field 11. This object-image shift in the y-direction y may be of approximately the same magnitude as a z-distance between the object plane 6 and the image plane 12.

The projection optics unit 10 may for example have an anamorphic form. For example, it has different imaging scales βx, βy in the x-direction x and y-direction y. The two imaging scales βx, βy of the projection optics unit 10 can be (βx, βy)=(+/−0.25, +/−0.125). A positive imaging scale β means imaging without image inversion. A negative sign for the imaging scale β means imaging with image inversion.

The projection optics unit 10 consequently leads to a reduction in size with a ratio of 4:1 in the x-direction x, i.e. in a direction perpendicular to the scanning direction.

The projection optics unit 10 leads to a reduction in size of 8:1 in the y-direction y, i.e. in the scanning direction.

Other imaging scales are likewise possible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 may be the same or may differ, depending on the embodiment of the projection optics unit 10. Examples of projection optics units with different numbers of such intermediate images in the x-direction x and the y-direction y are known from US 2018/0074303 A1.

In each case, one of the second facets 23 is assigned to exactly one of the first facets 21 in order to form a respective illumination channel for illuminating the object field 5. This may for example produce illumination according to the Köhler principle. The far field is decomposed into a multiplicity of object fields 5 using the first facets 21. The first facets 21 generate a plurality of images of the intermediate focus on the second facets 23 respectively assigned thereto.

The first facets 21 are each imaged onto the reticle 7 by an assigned second facet 23 with images overlaid over one another for the purpose of illuminating the object field 5. The illumination of the object field 5 is for example as homogeneous as possible. It can have a uniformity error of less than 2%. Field uniformity may be achieved by overlaying different illumination channels.

An arrangement of the second facets 23 may geometrically define the illumination of the entrance pupil of the projection optics unit 10. The intensity distribution in the entrance pupil of the projection optics unit 10 may be set by selecting the illumination channels, for example the subset of the second facets 23 that guide light. This intensity distribution is also referred to as illumination setting or illumination pupil filling.

A likewise preferred pupil uniformity in the region of portions of an illumination pupil of the illumination optics unit 4 that are illuminated in a defined manner may be achieved by a redistribution of the illumination channels.

Further aspects and details of the illumination of the object field 5 and, for example, of the entrance pupil of the projection optics unit 10 are described below.

The projection optics unit 10 may have for example a homocentric entrance pupil. The latter may be accessible. It may also be inaccessible.

The entrance pupil of the projection optics unit 10 regularly cannot be exactly illuminated with the second facet mirror 22. In the case of imaging by the projection optics unit 10 that telecentrically images the center of the second facet mirror 22 onto the wafer 13, the aperture rays often do not intersect at a single point. However, it is possible to find an area in which the spacing of the aperture rays that is determined in pairs becomes minimal. This area is the entrance pupil or an area conjugate thereto in real space. For example, this area exhibits a finite curvature.

It may be the case that the projection optics unit 10 has different poses of the entrance pupil for the tangential beam path and for the sagittal beam path. In this case, an imaging element, for example an optical component of the transfer optics unit, should be provided between the second facet mirror 22 and the reticle 7. With the aid of this optical element, the different poses of the tangential entrance pupil and the sagittal entrance pupil can be taken into account.

In the arrangement of the components of the illumination optics unit 4 illustrated in FIG. 1, the second facet mirror 22 is arranged in an area conjugate to the entrance pupil of the projection optics unit 10. The first facet mirror 20 is arranged so as to be tilted with respect to the object plane 6. The first facet mirror 20 is arranged so as to be tilted with respect to an arrangement plane defined by the deflection mirror 19. The first facet mirror 20 is arranged so as to be tilted with respect to an arrangement plane defined by the second facet mirror 22.

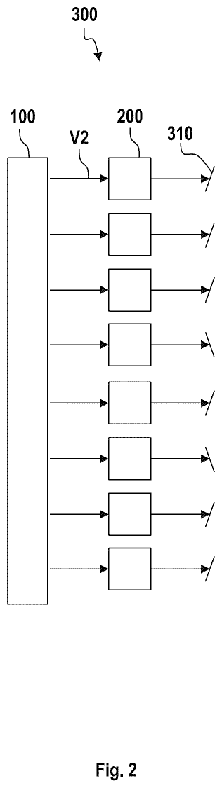

FIG. 2 shows a schematic illustration of one embodiment of an optical system 300 for a lithography apparatus or projection exposure apparatus 1, as shown for example in FIG. 1. Additionally, the optical system 300 in FIG. 2 may also be used in a DUV lithography apparatus, for example.

The optical system 300 in FIG. 2 has a plurality of actuatable optical elements 310. The optical system 300 is embodied here as a micromirror array, wherein the optical elements 310 are micromirrors. Each micromirror 310 is actuatable via an assigned actuator 200.

For example, a respective micromirror 310 can be tilted about two axes and/or displaced in one, two or three spatial axes via the assigned actuator 200. The reference signs only of the topmost row of these elements are depicted, for reasons of clarity.

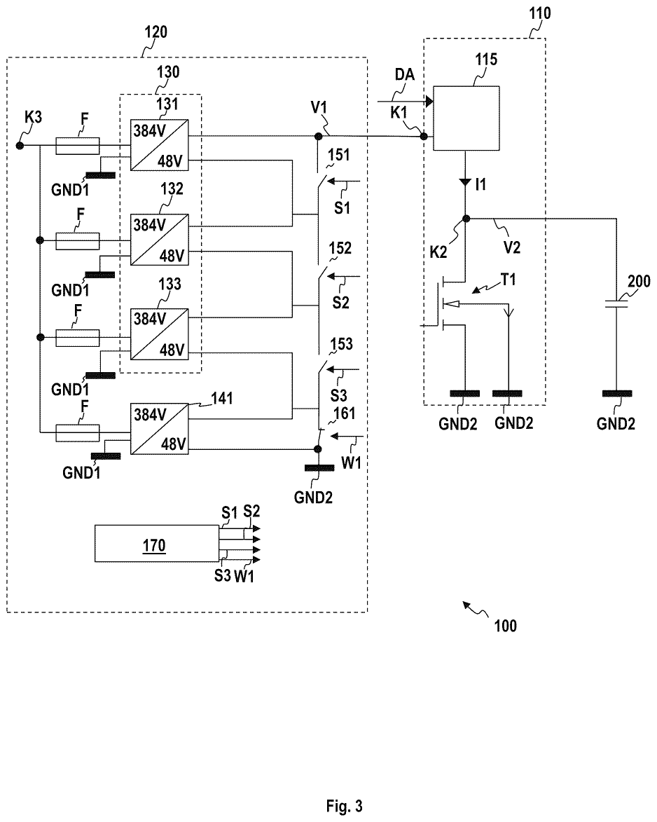

The control device 100 controls the respective actuator 200, for example using a control voltage V2 (see FIGS. 3 to 6). This is used to set a position of the respective micromirror 310. The control device 100 is described with reference to FIGS. 3 to 7 for example.

FIG. 3 illustrates a schematic block diagram of a first embodiment of a control device 100 for controlling an actuator 200 for actuating an optical element 310 in an optical system 4, 10. The actuator 200 is a capacitive actuator in the embodiments of FIGS. 3 to 6 and is shown in these FIGS. 3 to 6 as a capacitor.

The control device 100 according to FIG. 3 comprises an amplifier 110 and a supply device 120.

The amplifier 110 is configured to receive, at an input node K1, a supply voltage V1 provided by the supply device 120 and provide a control voltage V2 for the actuator 200 at an output node K2. The supply device 120 is coupled between the input node K1 of the amplifier 110 and an input node K3.

The amplifier 110 comprises a transistor T1, coupled to the output node K2, for amplifying the voltage at the control input of the transistor T1 into the control voltage V2. The amplifier 110 may also be referred to as output stage. For example, the amplifier 110 takes the form of a class A amplifier. For example, the transistor T1 is a field-effect transistor (FET). Alternatively, the transistor T1 may also take the form of a bipolar transistor. As an alternative to the class A amplifier, the amplifier 110 may also take the form of a class AB amplifier.

The supply device 120 is configured to provide the supply voltage V1 to the input node K1 of the amplifier 110. The input node K1 of the amplifier 110 forms the output node of the supply device 120 at the same time.

In the exemplary embodiment according to FIG. 3, the supply device 120 receives a voltage of 384 V at its input node K3 and outputs a voltage of 144 V on the output side (144 V=48 V+48 V+48 V). Hence, the supply device 120 in the exemplary embodiment according to FIG. 3 takes the form of a voltage reduction unit.

As shown in FIG. 3, the supply device 120 has a series connection 130, which can be coupled between the input node K1 and ground GND2, of a plurality N, with N≥2, of DC/DC converters 131-133 which serve to provide a respective DC voltage, for example 48 V in the exemplary embodiment according to FIG. 3. Without loss of generality, N=3 in FIG. 3. Hence the series connection 130 comprises three series-connected DC/DC converters 131, 132, 133. Moreover, the supply device 120 comprises a number M, with M≥1, of further DC/DC converters 141 which can be connected in series with the series connection 130 and serve to provide a respective DC voltage, for example 48 V in FIG. 3. Without loss of generality, M=1 in FIG. 3. The further DC/DC converter 141 may also be referred to as a reserve DC/DC converter. The respective DC/DC converter 131-133, 141 may optionally also have a separate input node with respective ground potential GND1. The ground potential GND1 at the input of the DC/DC converters 131-133, 141 is independent of the ground potential GND2 at the output of the DC/DC converters 131-133, 141 since these ground potentials can be galvanically isolated from each other.

Each of the N DC/DC converters 131-133 and each of the M further DC/DC converters 141 is assigned a respective controllable switch 151-153, 161. Thus, in the exemplary embodiment in FIG. 3, the switch 151 is assigned to the DC/DC converter 131, the switch 152 is assigned to the DC/DC converter 132, the switch 153 is assigned to the DC/DC converter 133, and the switch 161 is assigned to the further DC/DC converter 141. All switches 151-153, 161 are controllable switches; thus, the switch 151 is controllable via the control signal S1, the switch 152 is controllable via the control signal S2, the switch 153 is controllable via the control signal S3, and the switch 161 is controllable via the control signal W1.

In general, the N DC/DC converters 131-133 in the series connection 130 are designed such that a sum of their DC voltages provided in the connected state corresponds to a predetermined target value for the supply voltage V1. In the exemplary embodiment according to FIG. 3, the target value for the supply voltage V1=144 V. In the connected state, each of the three DC/DC converters 131-133 provides 48 V on the output side. The total of 3×48 V is 144 V.

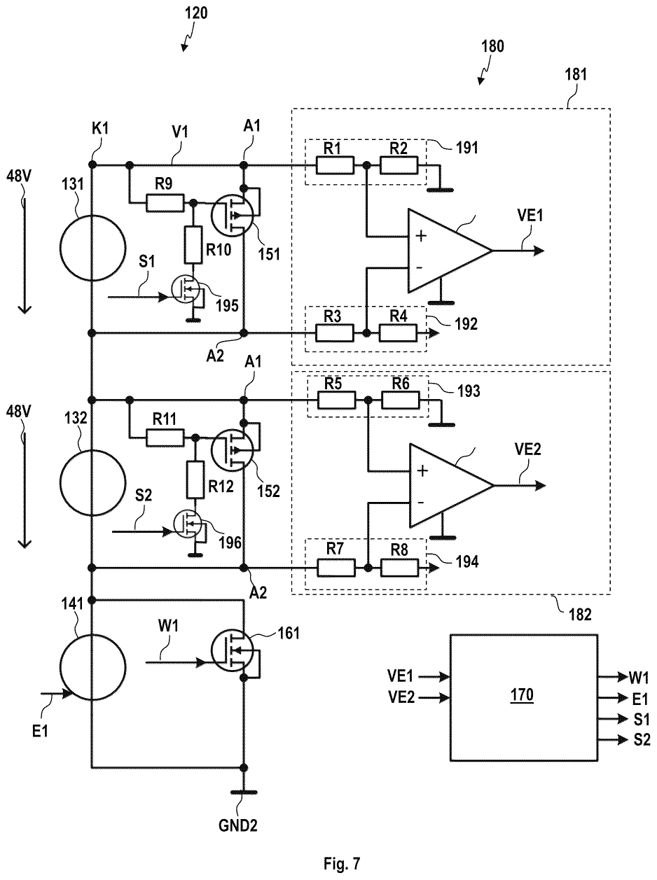

A control unit 170 is provided for the control of the N DC/DC converters 131-133 and the M further DC/DC converters 141 (see also FIG. 7). The control unit 170 is configured to generate the control signals S1-S3, W1 and control the switches 151-153, 161 via the control signals S1-S3, W1 generated.

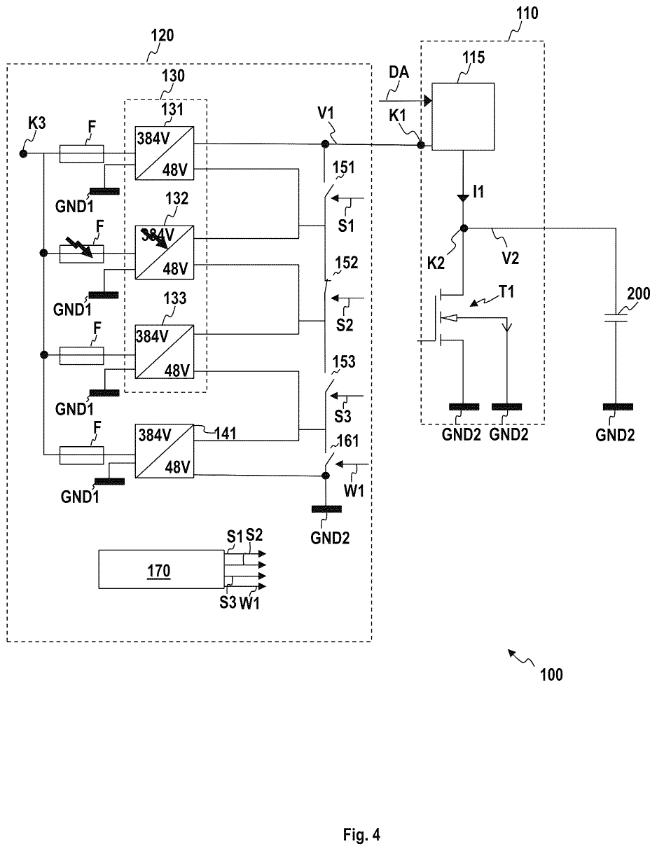

In the event of a detected fault in a specific DC/DC converter 132 from the connected N DC/DC converters 131-133, the control unit 170 is configured to both control the switch 152 assigned to the specific DC/DC converter 132 in such a way that the specific DC/DC converter 132 is shorted and control a switch 161 assigned to a specific one of the further M DC/DC converters 141 in such a way that the specific further DC/DC switch 141 is connected. FIG. 4 shows this and hence the control device 100 according to FIG. 3 in the event of a fault and its subsequent response.

A respective fuse F may be connected between the input node K3 of the supply device 120 and the respective DC/DC converter 131-133, 141. In embodiments, the fuses F may also be arranged outside the supply device 120. The respective fuse F protects the individual supply paths in order to safeguard the 348 V input node K3. The DC/DC converters 131-133, 141 can be galvanically isolated. The galvanic isolation of the DC/DC converters 131-133, 141 from 384 V to 48 V results in a simple guarantee of the series connection of the desired DC/DC converters between ground GND2 and the input node K1 of the amplifier 110.

An evaluation device 180 for detecting faults in the N DC/DC converters 131-133 is explained with reference to FIG. 7.

If, like in the example according to FIG. 4, a fault is detected in the DC/DC converter 132 and the fuse F assigned to the DC/DC converter 132 is also triggered as a result, then the control unit 170 controls the switch 152 in such a way that the latter closes and hence bridges the DC/DC converter 132. Moreover, and especially simultaneously, the control unit 170 controls the switch 161 assigned to the reserve DC/DC converter 141 in such a way that the switch opens so that the DC output voltage of 48 V of the reserve DC/DC converter 141 contributes to the supply voltage V1 applied to the input node K1 of the amplifier 110. Hence, the following DC/DC converters each supply 48 V to the supply voltage V1 of 144 V in FIG. 4: the DC/DC converter 131, the DC/DC converter 133 and the reserve DC/DC converter 141. The faulty DC/DC converter 132 is bridged by the assigned switch 152, as shown in FIG. 4.

As already explained above, the control device 100 according to FIGS. 3 and 4 also comprises a provision unit 115. The provision unit 115 is configured to set the quiescent current I1 for the amplifier 110 on the basis of a specific desired dynamic DA for the amplifier 110. In this case, the provision unit 115 is configured to set the quiescent current I1 for the amplifier 110 on the basis of the determined desired dynamic DA for the amplifier 110 and feed the quiescent current into the output node K2 of the amplifier 110.

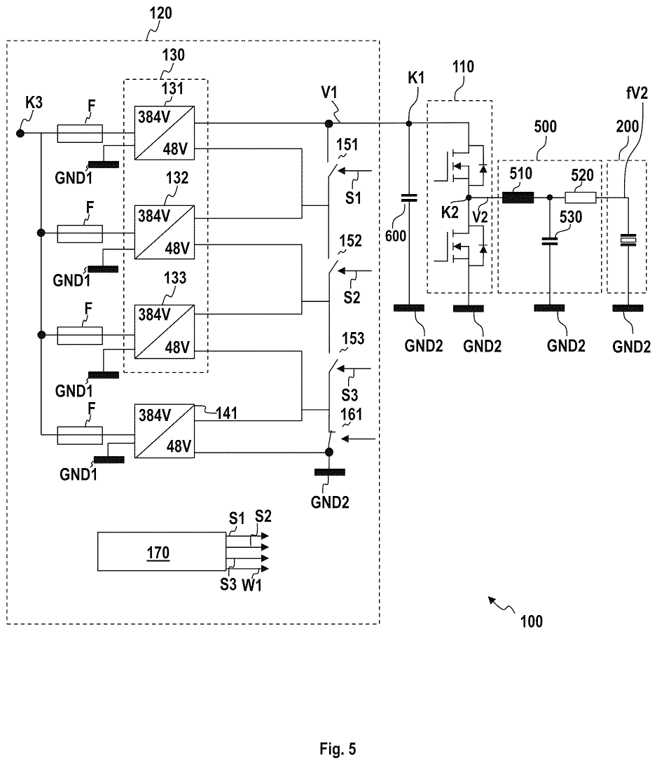

FIG. 5 shows a schematic block diagram of a second embodiment of a control device 100 for controlling an actuator 200 for actuating an optical element 310 in an optical system 4, 10.

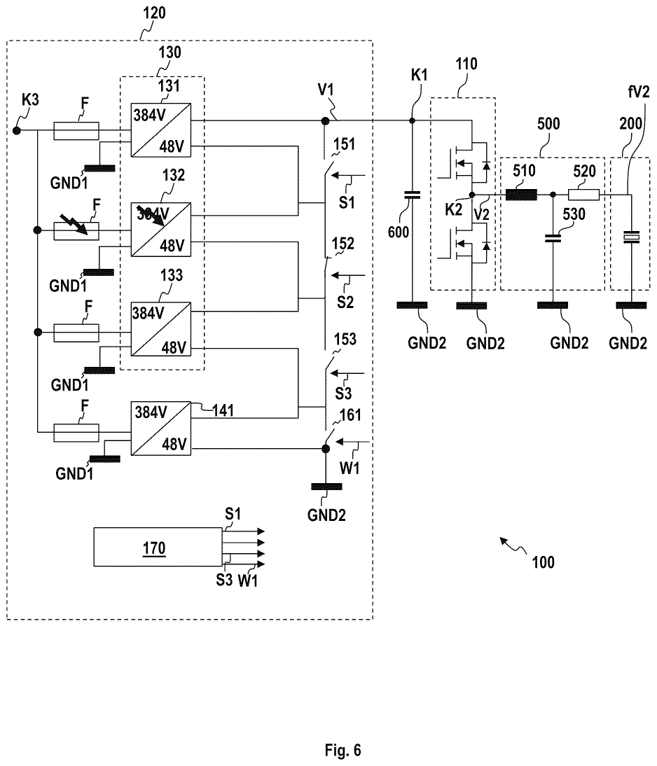

The second embodiment of the control device 100 according to FIG. 5 comprises an amplifier 110 and a supply device 120 for providing the supply voltage V1 to the input node K1 of the amplifier 110. The supply device 120 illustrated in FIG. 5 corresponds to the supply device 120 in FIG. 3, and hence the response of the supply device 120 according to FIG. 6 corresponds to that of the supply device according to FIG. 4.

The amplifier 110 according to FIG. 5 takes the form of a switching amplifier which is configured to amplify the supply voltage V1 provided at the input node K1 into the control voltage V2 provided at the output node K2 for the actuator 200. A DC link capacitor 600 is connected between the node K1 and ground GND2.

In FIG. 5, a filter unit 500 is connected between the output node K2 of the switching amplifier 110 and the actuator 200. The filter unit 500 is configured to filter the control voltage V2 provided by the switching amplifier 110 and, on the basis thereof, provide a filtered output voltage fV2 for the actuator 200 on the output side. The filter unit 500 comprises, for example, an inductor 510, for example a coil, connected in series with the actuator 200, and also a resistor 520, for example an ohmic resistor, and a capacitor 530 connected in parallel with the actuator 200. The specific choice of values for the inductor 510, the resistor 520 and the capacitor 530 depends on the actuator 200 to be controlled and on the desired properties of the filtered control signal fV2.

FIG. 7 illustrates a schematic block diagram of an embodiment of a supply device 120 for providing the supply voltage V1 for the amplifier 110 (not shown in FIG. 7) and of an embodiment of an evaluation device 180 for detecting faults of the N DC/DC converters 131, 132 in the series connection 130 in the supply device 120.

In the exemplary embodiment according to FIG. 7, the supply device 120 has two DC/DC converters 131, 132, with N=2. The DC/DC converters 131, 132 are illustrated schematically in FIG. 7 and each provide a DC voltage of 48 V on the output side.

Moreover, the supply device 120 according to FIG. 7 has a further DC/DC converter 141 (reserve DC/DC converter 141). The reserve DC/DC converter 141 is configured to output a DC voltage of 48 V when connected.

As shown in FIG. 7, the DC/DC converter 131 is assigned a switch 151 which is in the form of a PMOS transistor in the embodiment according to FIG. 7. Furthermore, the DC/DC converter 132 in FIG. 7 is assigned a switch 152 which is in the form of a PMOS transistor in the embodiment according to FIG. 7. The reserve DC/DC converter 141 is assigned a switch 161 which is in the form of an NMOS transistor in the embodiment according to FIG. 7.

Moreover, the supply device 120 according to FIG. 7 has an evaluation device 180 which is configured to detect faults in the DC/DC converters 131, 132. The evaluation device 180 according to FIG. 7 has a respective evaluation circuit 181, 182 for each of the DC/DC converters 131, 132.

As illustrated in FIG. 7, the switch 151, 152 assigned to the respective DC/DC converter 131, 132 is coupled between the output terminals A1, A2 of the DC/DC converter 131, 132, with the respective evaluation circuit 181, 182 being connected in parallel with the assigned switch 151, 152. Thus, the evaluation circuit 181 is connected to the output terminals A1, A2 of the DC/DC converter 131. The evaluation circuit 181 comprises a first voltage divider 191 connected to the first output terminal A1, a second voltage divider 192 connected to the second output terminal A2 and a comparator C. In this case, the non-inverting input of the comparator C is coupled to the center tap of the first voltage divider 191, and the inverting input of the comparator C is coupled to the center tap of the second voltage divider 192. In this case, the comparator C is configured to provide a comparison result VE1 on the basis of the signals provided at its inputs. In order to reduce the input signals for the comparator C to the voltage level suitable for the comparator C, the resistors R1 and R2 in the first voltage divider 191 and the resistors R3 and R4 in the second voltage divider 192 have suitable resistance values. For the example of the DC/DC converter 131 for converting an input voltage of 384 V to an output voltage of 48 V, the resistors R1, R2, R3 and R4 for example have the following values: R1=93 kΩ, R2=3 kΩ, R3=46 kΩ and R4=1 kΩ.

The evaluation circuit 182 for the DC/DC converter 132 has an analogous construction, with the resistors R5 and R6 in the first voltage divider 193 and the resistors R7 and R8 in the second voltage divider 194 for example having the following values: R5=45 kΩ, R6=3 kΩ, R7=18 kΩ and R12=1 kΩ.

As shown in FIG. 7, the evaluation circuit 181 provides a comparison result VE1, and the evaluation circuit 182 provides a comparison result VE2. The comparison results VE1 and VE2 are provided to the control unit 170. Here, the control unit 170 is configured to provide the control signals S1 and S2 for controlling the switches 152, 152 assigned to the DC/DC converters 131, 132, the control signal W1 for controlling the switch 161 assigned to the reserve DC/DC converter 141 and an enable signal E1 for connecting the reserve DC/DC converter 141 in the event of a detected fault at one of the DC/DC converters 131, 132.

An NMOS transistor 195 is used to control the PMOS transistor 151 via the control signal S1. A voltage divider made of the resistors R9 and R10 is used so as to be able to control the gate terminal of the PMOS transistor 151 at a suitable voltage level. In this case, the gate terminal of the PMOS transistor 151 is coupled to the center tap of the voltage divider composed of the resistors R9, R10. The further terminal of the resistor R9 is coupled to the first output terminal A1 of the DC/DC converter 131, with the further terminal of the resistor R10 being connected to the drain terminal of the NMOS transistor 195. The source terminal of the NMOS transistor 195 is connected to ground. The NMOS transistor 195 receives the control signal S1 for controlling the PMOS transistor 151 at its gate terminal.

The PMOS transistor 152 is controlled analogously. Accordingly, an NMOS transistor 196 is used to control the PMOS transistor 152 via the control signal S2. A voltage divider made of the resistors R11 and R12 is used so as to be able to control the gate terminal of the PMOS transistor 152 at a suitable voltage level. In this case, the gate terminal of the PMOS transistor 152 is coupled to the center tap of the voltage divider composed of the resistors R11, R12. The further terminal of the resistor R11 is coupled to the first output terminal A1 of the DC/DC converter 132, with the further terminal of the resistor R12 being connected to the drain terminal of the NMOS transistor 196. The source terminal of the NMOS transistor 196 is connected to ground. The NMOS transistor 196 receives the control signal S2 for controlling the PMOS transistor 152 at its gate terminal.

Although the present disclosure has been described with reference to exemplary embodiments, it may be modified in a variety of ways.

### LIST OF REFERENCE SIGNS

1 Projection exposure apparatus
2 Illumination system
3 Light source
4 Illumination optics unit
5 Object field
6 Object plane
7 Reticle
8 Reticle holder
9 Reticle displacement drive
10 Projection optics unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
100 Control device
110 Amplifier
115 Provision unit
120 Supply device
130 Series connection
131 DC/DC converter
132 DC/DC converter
133 DC/DC converter
141 Further DC/DC converter (reserve DC/DC converter)
151 Switch of a DC/DC converter
152 Switch of a DC/DC converter
153 Switch of a DC/DC converter
161 Switch of a further DC/DC converter
170 Control unit
180 Evaluation device
181 Evaluation circuit
182 Evaluation circuit
191 Voltage divider
192 Voltage divider
193 Voltage divider
194 Voltage divider
200 Actuator
300 Optical system
310 Optical element
500 Filter unit
510 Inductor
520 Resistor
530 Capacitor
600 DC link capacitor
C Comparator
DA Desired Dynamic
E1 Enable signal
GND1 Ground potential
GND2 Ground potential
I1 Quiescent current
K1 Input node of the amplifier
K2 Output node of the amplifier
K3 Input node of the supply device
M1 Mirror
M2 Mirror
M3 Mirror
M4 Mirror
M5 Mirror
M6 Mirror
R1 Resistor
R2 Resistor
R3 Resistor
R4 Resistor
R5 Resistor
R6 Resistor
R7 Resistor
R8 Resistor
R9 Resistor
R10 Resistor
R11 Resistor
R12 Resistor
S1 Control signal for a DC/DC converter
S2 Control signal for a DC/DC converter
S3 Control signal for a DC/DC converter
T1 Transistor
V1 Supply voltage
V2 Control voltage
fV2 Filtered control voltage
W1 Control signal for a further DC/DC converter

What is claimed is:

1. A control device, comprising:
an amplifier comprising an input node and an output node, the amplifier configured to receive a supply voltage at the input node and to provide a control voltage for an actuator at the output node, the actuator configured to actuate an optical element of an optical system;
a supply device configured to provide the supply voltage to the input node, the supply device comprising:
a series connection couplable between the input node and ground, the series connection comprising a number N of DC/DC converters, each of the N DC/DC converters configured to provide a DC voltage, N being at least two; and
a number M of further DC/DC converters connectable in series with the series connection, each of the M further DC/DC converters configured to provide a DC voltage, M being at least one; and
a control unit configured to control the N DC/DC converters and the M further DC/DC converters,
wherein:
for each of the N DC/DC converters, a controllable switch is assigned to the DC/DC converter to connect or short the DC/DC converter to provide the supply voltage;
for each of the M further DC/DC converters, a controllable switch is assigned to the DC/DC converter to connect or short the DC/DC converter to provide the supply voltage;
the control unit is configured so that, when a fault is detected in a specific DC/DC converter of the N DC/DC converters, the control unit controls:
i) the switch assigned to the specific one of the N DC/DC converters so that the specific one of the N DC/DC converters is shorted; and
ii) the switch assigned to a specific one of the M further DC/DC converters so that the specific one of the specific one of the M further DC/DC converters is connected.

2. The control device of claim 1, wherein the N DC/DC converters are configured so that a sum of their DC voltages provided in the connected state corresponds to a target value for the supply voltage.

3. The control device of claim 1, wherein the control device comprises an evaluation device configured to detect faults in the N DC/DC converters.

4. The control device of claim 3, wherein for each of the N DC/DC converters:
the evaluation device comprises an evaluation circuit connected in parallel with the controllable switch assigned to the DC/DC converter;
the DC/DC converter comprises output terminals;
the controllable switch assigned to the DC/DC converter is coupled between the output terminals of the DC/DC converter.

5. The control device of claim 4, wherein, for each of the N DC/DC converters, the evaluation circuit comprises:
a first voltage divider connected to a first one of the output terminals;
a voltage divider connected to a second one of the output terminals; and
a comparator configured to provide a comparison result, a non-inverting input of the comparator coupled to a center tap of the first voltage divider, and an inverting input of the comparator coupled to a center tap of the second voltage divider.

6. The control device of claim 5, wherein:
the control unit is configured to receive the N comparison results provided by the comparators of the N evaluation circuits; and
the control unit is configured to provide, based on the received comparison results:
i) a plurality N of control signals to control the N controllable switches;
ii) a number M of control signals to control the M controllable switches assigned to the M further DC/DC converters; and
iii) a signal to connect the specific one of the M further DC/DC converters when the fault is detected in the specific one of the N DC/DC converters.

7. The control device of claim 1, wherein:
the amplifier is configured to amplify the supply voltage provided at the input node into the control voltage provided at the output node based on a quiescent current of the amplifier; and
the control device further comprises a provision unit configured to set the quiescent current based on a desired dynamic for the amplifier.

8. The control device of claim 7, wherein the provision unit is configured to: i) set the quiescent current based on the desired dynamic for the amplifier; and ii) provide the quiescent current to the output node of the amplifier.

9. The control device of claim 1, wherein the amplifier comprises a switching amplifier, and the control device further comprises a filter unit comprising an inductor connected between the actuator and the switching amplifier.

10. The control device of claim 1, wherein the control device comprises an evaluation device configured to detect faults in the N DC/DC converters, and the N DC/DC converters are configured so that a sum of their DC voltages provided in the connected state corresponds to a target value for the supply voltage.

11. The control device of claim 1, wherein:
the N DC/DC converters are configured so that a sum of their DC voltages provided in the connected state corresponds to a target value for the supply voltage;
the amplifier is configured to amplify the supply voltage provided at the input node into the control voltage provided at the output node based on a quiescent current of the amplifier; and
the control device further comprises a provision unit configured to set the quiescent current based on a desired dynamic for the amplifier.

12. The control device of claim 1, wherein the N DC/DC converters are configured so that a sum of their DC voltages provided in the connected state corresponds to a target value for the supply voltage, the amplifier comprises a switching amplifier, and the control device further comprises a filter unit comprising an inductor connected between the actuator and the switching amplifier.

13. The control device of claim 1, wherein:
the control device comprises an evaluation device configured to detect faults in the N DC/DC converters;
the amplifier is configured to amplify the supply voltage provided at the input node into the control voltage provided at the output node based on a quiescent current of the amplifier; and
the control device further comprises a provision unit configured to set the quiescent current based on a desired dynamic for the amplifier.

14. The control device of claim 1, wherein the control device comprises an evaluation device configured to detect faults in the N DC/DC converters, the amplifier comprises a switching amplifier, and the control device further comprises a filter unit comprising an inductor connected between the actuator and the switching amplifier.

15. An optical system, comprising:
an optical element;
an actuator configured to actuate the optical element; and
a control device according to claim 1, wherein the control device is configured to control the actuator.

16. The optical system of claim 15, wherein the optical system comprises an illumination optics unit or a projection optics unit.

17. An apparatus, comprising:
an optical element;
an actuator configured to actuate the optical element; and
a control device according to claim 1,
wherein the control device is configured to control the actuator, and the apparatus is a lithography apparatus.

18. The apparatus of claim 17, further comprising:
an illumination optics; and
a projection optics,
wherein:
the illumination optics is configured to illuminate an object field in an object plane of the projection optics;
the projection optics is configured to image the object plane into an image plane of an image field of the projection optics; and
the illumination optics comprises the optical element, the actuator and the control device.

19. The apparatus of claim 17, further comprising:
an illumination optics; and
a projection optics,
wherein:
the illumination optics is configured to illuminate an object field in an object plane of the projection optics;
the projection optics is configured to image the object plane into an image plane of an image field of the projection optics; and
the projection optics comprises the optical element, the actuator and the control device.

20. A method of using a lithography apparatus comprising an illumination optical unit and a projection optical unit, the method comprising:
using the illumination optical unit to illuminate an object field in an object plane of the projection optical unit; and
using the projection optical unit to image the object field into an image field of an image plane of the projection optical unit,
wherein the projection optics or the illumination optics comprises:
an optical element;
an actuator configured to actuate the optical element; and
a control device according to claim 1, the control device being configured to control the actuator.
